(19) United States
(12) Patent Application Publication
(10) Pub. No.: US 2026/0254430 A1
(43) Pub. Date: Aug. 27, 2026

(54) DUPLEXER AND COMMUNICATION DEVICE

(71) Applicant: KYOCERA Corporation, Kyoto-shi, Kyoto (JP)

(72) Inventor: Hironori KII, Soraku-gun (JP)

(73) Assignee: KYOCERA Corporation, Kyoto-shi, Kyoto (JP)

(21) Appl. No.: 18/877,021

(22) PCT Filed: Jun. 9, 2023
(86) PCT No.: PCT/JP2023/021467

§ 371 Date: Dec. 19, 2024

(30) Foreign Application Priority Data
Jun. 21, 2022 (JP) 2022-099428

(51) Int. Cl. H03H 7/01; H03H 7/18; H04B 1/40

(52) U.S. Cl. CPC H03H 7/0115; H03H 7/18; H04B 1/40

(57) ABSTRACT

In a branching filter, a first filter is connects a common terminal to a first terminal; comprising a first passband. A second filter is configured connects the common terminal to a second terminal; comprising a second passband. A third filter is connects a node to the second terminal, and corresponds to the first passband. A fourth filter is connects the node to the first terminal; corresponding to the second passband. A 180° phase shifter is closer to the first terminal than the first and fourth filters are, closer to the second terminal than the second and third filters are. The 180° phase shifter makes phases of output signals from a path extending from the first terminal through the first filter and second filters to the second terminal and a path extending from the first terminal through the fourth and third filters to the second terminal opposite each other.

### TECHNICAL FIELD

The present disclosure relates to a branching filter including two or more filters and also relates to a communication apparatus including the branching filter.

### BACKGROUND OF INVENTION

As a branching filter, a duplexer including a transmission filter and a reception filter is known (e.g., Patent Literature 1). The transmission filter connects a transmission terminal to an antenna terminal, filters a transmission signal received from the transmission terminal, and outputs the resulting signal to the antenna terminal. The reception filter connects the antenna terminal to a reception terminal, filters a reception signal received from the antenna terminal, and outputs the resulting signal to the reception terminal. In another perspective, the reception filter blocks a transmission signal output from the transmission filter, and does not allow the transmission signal to be received by the reception terminal. In practice, however, a signal output from the transmission filter (e.g., transmission signal) is not completely blocked by the reception filter. That is, a leakage signal passing through the reception filter toward the reception terminal is generated.

In Patent Literature 1, such a leakage signal is reduced and isolation characteristics are improved. Specifically, in Patent Literature 1, a delay line and a resonator, which are connected in parallel to the transmission filter and the reception filter, are provided between the transmission terminal and the reception terminal. Upon receiving a transmission signal from the transmission terminal, the delay line and the resonator generate a cancellation signal having an amplitude similar to that of a leakage signal and a phase opposite that of the leakage signal, and output the generated cancellation signal to the reception terminal. This allows the cancellation signal and the leakage signal to be cancelled each other out and reduces the leakage signal.

### CITATION LIST

### Patent Literature

Patent Literature 1: Japanese Unexamined Patent Application Publication No. 2013-118611

### SUMMARY

In an embodiment of the present disclosure, a branching filter includes a first filter, a second filter, a third filter, a fourth filter, and a 180° phase shifter. The first filter is configured to connect a common terminal to a first terminal, and corresponds to a first passband. The second filter is configured to connect the common terminal to a second terminal, and corresponds to a second passband not overlapping the first passband. The third filter is configured to connect a node disposed at a branch point to the second terminal, and corresponds to the first passband. The fourth filter is configured to connect the node to the first terminal, and corresponds to the second passband. The 180° phase shifter is disposed closer to the first terminal than the first filter and the fourth filter are, or disposed closer to the second terminal than the second filter and the third filter are. The 180° phase shifter is configured to make phases of output signals from a path extending from the first terminal through the first filter and the second filter to the second terminal and a path extending from the first terminal through the fourth filter and the third filter to the second terminal opposite each other. The output signals are based on the same input signal to the paths.

In an embodiment of the present disclosure, a communication apparatus includes the branching filter, an antenna connected to the common terminal, a resistive element connected to the node, and an integrated circuit element connected to the first terminal and the second terminal.

### BRIEF DESCRIPTION OF THE DRAWINGS

FIG. 1 is a circuit diagram illustrating a configuration of a branching filter according to an embodiment.

FIG. 2 is a schematic perspective view illustrating a first exemplary structure of the branching filter illustrated in FIG. 1.

FIG. 3 is a plan view illustrating an exemplary configuration of a chip of the branching filter illustrated in FIG. 2.

FIG. 4 is a schematic perspective view illustrating a second exemplary structure of the branching filter illustrated in FIG. 1.

FIG. 5 is a plan view illustrating a configuration example of a chip of the branching filter illustrated in FIG. 4.

FIG. 6 is a block diagram illustrating a configuration of a communication apparatus according to an embodiment.

### DESCRIPTION OF EMBODIMENTS

Embodiments according to the present disclosure will now be described with reference to the drawings. Note that the drawings used in the following description are schematic ones. Therefore, for example, dimensional ratios in the drawings do not necessarily match actual ones. Dimensional ratios and the like may vary from one drawing to another. Specific shapes and/or dimensions may be exaggerated, or details may be omitted. However, this does not deny that actual shapes and/or dimensions may be as illustrated in the drawings, or that features of shapes and/or dimensions may be extracted from the drawings.

### Overview of Branching Filter according to Embodiments

An overview of a duplexer 1 (an example of branching filter) according to an embodiment will now be described. In the description of the overview of the duplexer 1, for a matter that can have various configurations, a specific configuration of the matter may be described as an example for convenience, without particularly stated.

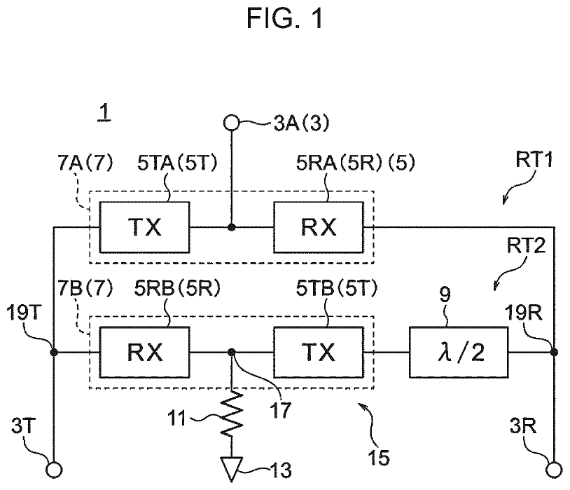

FIG. 1 is a circuit diagram illustrating a configuration of the duplexer 1 (an example of branching filter) according to an embodiment.

The duplexer 1 includes a first transmission filter 5TA configured to filter a transmission signal received by a transmission terminal 3T from the outside and output the resulting signal to an antenna terminal 3A, and a first reception filter 5RA configured to filter a reception signal received by an antenna terminal 3A from an antenna and output the resulting signal to a reception terminal 3R. The first transmission filter 5TA attenuates signals outside a transmission band (or passes signals in the transmission band). The first reception filter 5RA attenuates signals outside a reception band (or passes signals in the reception band). The transmission band and the reception band do not overlap. The first transmission filter 5TA and the first reception filter 5RA can be considered as ones that constitute a first duplexer 7A.

A transmission signal passed through the first transmission filter 5TA from the transmission terminal 3T is attenuated (or blocked) by the first reception filter 5RA and is basically (ideally) not output to the reception terminal 3R. In practice, however, a leakage signal passing through the first reception filter 5RA and leaking to the reception terminal 3R is generated. To reduce such a leakage signal, the duplexer 1 includes, between the transmission terminal 3T and the reception terminal 3R, a parallel path 15 connected in parallel to the first duplexer 7A.

The parallel path 15 includes, for example, a second duplexer 7B having basically the same configuration as the first duplexer 7A, and a phase shifter 9 connected in series to the second duplexer 7B. The second duplexer 7B includes a second transmission filter 5TB and a second reception filter 5RB having basically the same configuration as the first transmission filter 5TA and the first reception filter 5RA. The order of connection of the second transmission filter 5TB and the second reception filter 5RB to the transmission terminal 3T and the reception terminal 3R is opposite the order of connection of the first transmission filter 5TA and the first reception filter 5RA to the transmission terminal 3T and the reception terminal 3R. The phase shifter 9 shifts the phase of a received signal by 180° and outputs the resulting signal.

A transmission signal received by the transmission terminal 3T from the outside is basically blocked by the second reception filter 5RB and thus does not flow into the parallel path 15. Therefore, as in the case of absence of the parallel path 15, the transmission signal flows to the first transmission filter 5TA. In other words, ideally, insertion of the parallel path 15 does not cause insertion loss. Similarly, a reception signal passed through the first reception filter 5RA from the antenna terminal 3A is basically blocked by the second transmission filter 5TB and thus does not flow into the parallel path 15. Therefore, ideally, for the reception signal as well, insertion of the parallel path 15 does not cause insertion loss.

On the other hand, as can be understood from the fact that a leakage signal passing through the first transmission filter 5TA and the first reception filter 5RA from the transmission terminal 3T toward the reception terminal 3R is generated, the transmission signal from the transmission terminal 3T partially passes through the second reception filter 5RB in practice. The passing signal (which will hereinafter be also referred to as “cancellation signal”) passes through the second duplexer 7B having the same configuration (or the same characteristics) as the first duplexer 7A, and thus has a strength (e.g., voltage, current, or power; the same applies hereinafter) similar to the strength of the leakage signal. Since the phase shifter 9 shifts the phase of the cancellation signal by 180°, the cancellation signal has a phase opposite that of the leakage signal. Accordingly, the two signals cancel each other out. This reduces the leakage signal output from the reception terminal 3R to the outside of the duplexer 1.

The parallel path 15 includes, between the second reception filter 5RB and the second transmission filter 5TB, a node 17 connected to a resistive element 11. The resistive element 11 is connected to the node 17 and a reference potential portion 13. For example, the resistive element 11 contributes to reproducing, in the cancellation signal passing through the second duplexer 7B, the influence of the antenna terminal 3A on the leakage signal passing through the first duplexer 7A. This makes it easier for the leakage signal and the cancellation signal to cancel each other out. The resistive element 11 may be included in the duplexer 1, or may be an element outside the duplexer 1.

The duplexer 1, such as that described above, may be implemented by various structures.

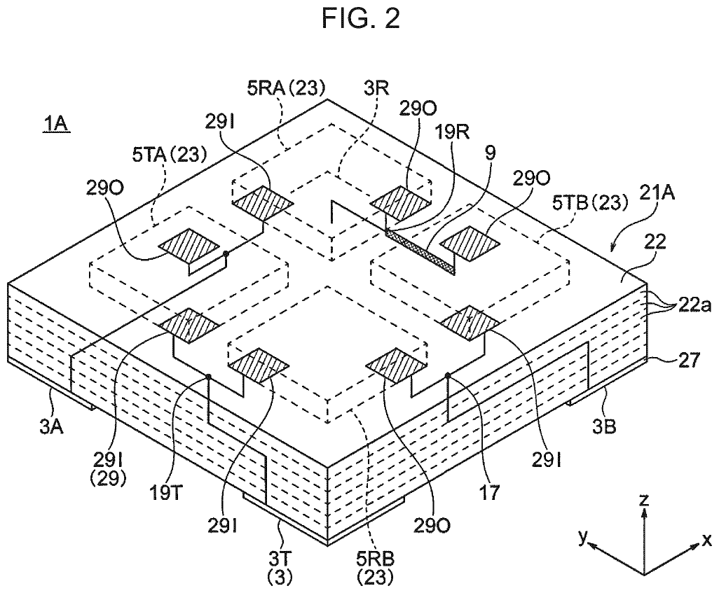

For example, in a first exemplary structure illustrated in FIG. 2, four chips 23 are mounted on a multilayer substrate 21A. The four chips 23 constitute the first transmission filter 5TA, the first reception filter 5RA, the second transmission filter 5TB, and the second reception filter 5RB. The phase shifter 9 is constituted by a transmission line in the multilayer substrate 21A.

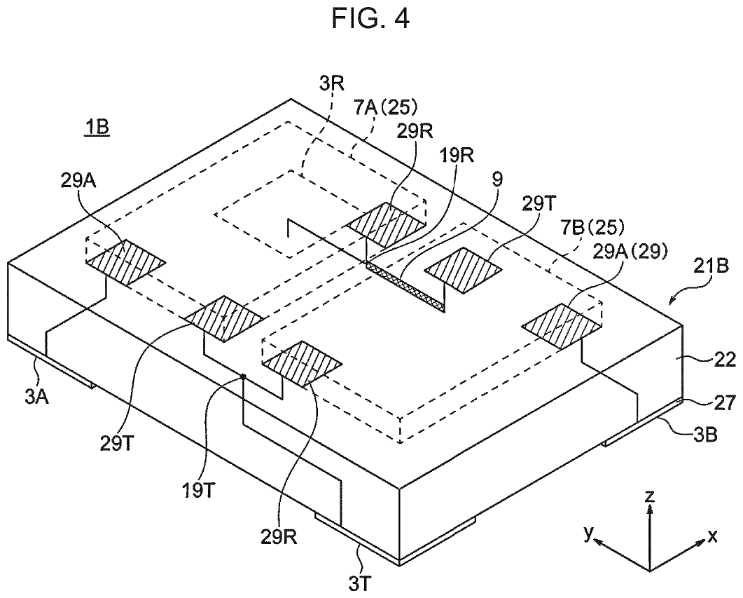

For example, in a second exemplary structure illustrated in FIG. 4, two chips 25 are mounted on a multilayer substrate 21B. The two chips 25 constitute the first duplexer 7A and the second duplexer 7B. The phase shifter 9 is constituted by a transmission line in the multilayer substrate 21B.

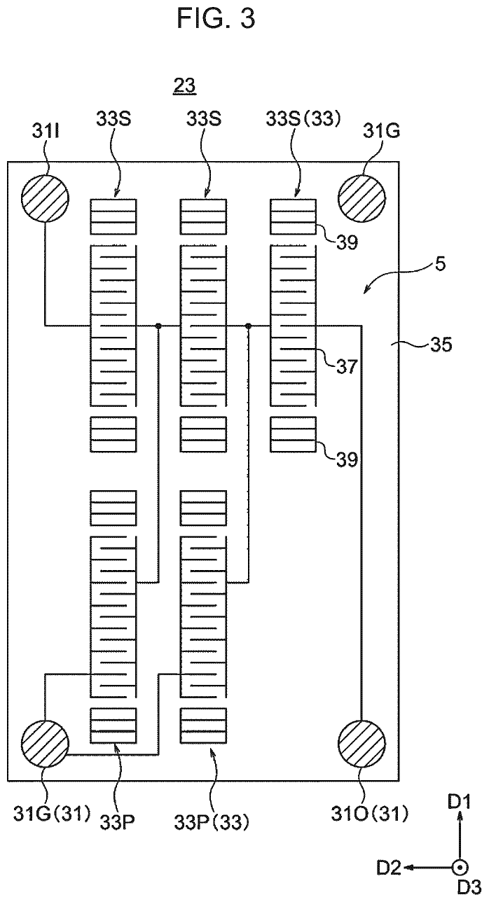

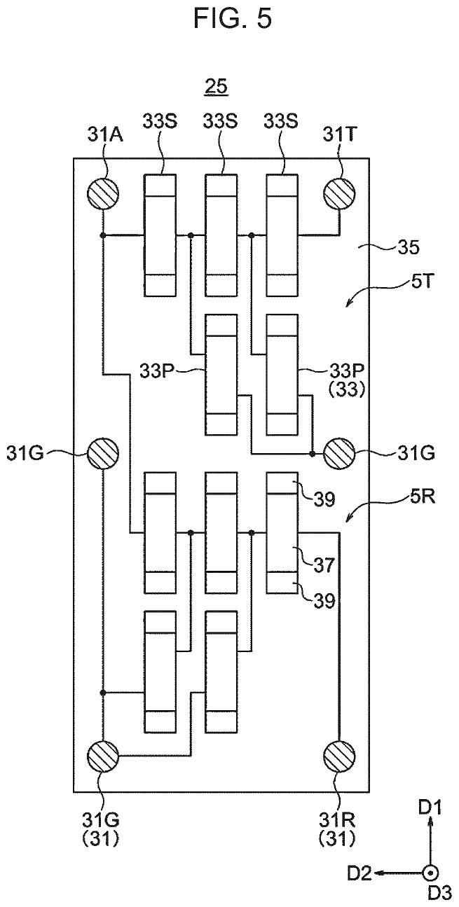

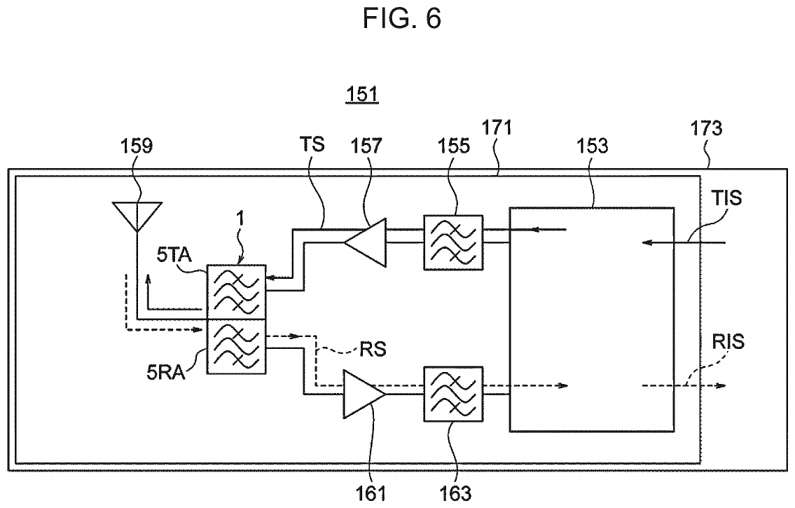

An overview of the duplexer 1 according to embodiments is that described above. The duplexer 1 will now be described roughly in the following order.
1. General Duplexer (FIG. 1)
   1.1. Filter
   1.2. Phase Shifter
   1.3. Resistive Element
   1.4. First Duplexer and Second Duplexer
2. Exemplary Structures of Duplexer
   2.1. First Exemplary Structure (FIG. 2 and FIG. 3)
      2.1.1. Overall Configuration of Duplexer
      2.1.2. Multilayer Substrate
      2.1.3. Chip
      2.1.4. Exemplary Structure of Connection
      2.1.5. Exemplary Structure of Phase Shifter
   2.2. Second Exemplary Structure (FIG. 4 and FIG. 5)
   2.3. Other Exemplary Structures
   2.4. Exemplary Structure of Node
3. Communication Device including Duplexer (FIG. 6)
4. Summary of Embodiments

### 1. General Duplexer

In the following description, the antenna terminal 3A, the transmission terminal 3T, and the reception terminal 3R may be referred to as “terminal 3” without distinction. The first duplexer 7A and the second duplexer 7B may be referred to as “duplexer 7” without distinction. The first transmission filter 5TA and the second transmission filter 5TB may be referred to as “transmission filter 5T” without distinction. The first reception filter 5RA and the second reception filter 5RB may be referred to as “reception filter 5R” without distinction. The transmission filter 5T and the reception filter 5R may be referred to as “filter 5” without distinction.

A path extending from the transmission terminal 3T through the first duplexer 7A to the reception terminal 3R is referred to as a first path RT1. A path extending from the transmission terminal 3T through the second duplexer 7B to the reception terminal 3R is referred to as a second path RT2. A branch point at which a path from the transmission terminal 3T branches off toward the first transmission filter 5TA and the second reception filter 5RB is referred to as a first branch point 19T. A branch point at which a path from the reception terminal 3R branches off toward the first reception filter 5RA and the second transmission filter 5TB is referred to as a second branch point 19R.

Unlike the configuration illustrated in FIG. 1, the transmission terminal 3T and the first branch point 19T may be the same. Similarly, the reception terminal 3R and the second branch point 19R may be the same.

### 1.1. Filter

The filter 5 is, for example, a bandpass filter configured to pass signals in a predetermined passband (transmission band or reception band) as described above. The passband (center frequency and bandwidth) may be any band. For example, the passband may be located within the range of 300 MHz to 10 GHz. The passband may be in accordance with a predetermined standard. The passband may correspond to one passband defined by a standard, or may include two or more passbands defined by a standard. Either the transmission band or the reception band may be located on the high frequency side.

In the illustrated example, the filter 5 receives an unbalanced signal and outputs an unbalanced signal. An unbalanced signal may be, for example, one signal whose signal level varies with respect to a reference potential. The filter 5 may receive a balanced signal and/or output a balanced signal. A balanced signal may be, for example, two signals whose phases are opposite. When a balanced signal is used, for example, all the filters 5 may be ones that accommodate input and output of a balanced signal and are each provided with two terminals, or an element for mutual conversion between unbalanced and balanced signals may be provided at an appropriate position.

For example, the second transmission filter 5TB has the same characteristics (e.g., transmission characteristic, delay time, and/or impedance characteristic; the same applies hereinafter) as the first transmission filter 5TA. Examples of the second transmission filter 5TB include one having the same configuration (structure) as the first transmission filter 5TA. Theoretically, however, a configuration different from that of the first transmission filter 5TA can implement the second transmission filter 5TB having the same characteristics as the first transmission filter 5TA.

Even when the characteristics of the second transmission filter 5TB are the same as the characteristics of the first transmission filter 5TA, not all the various characteristics need to be the same at various frequencies. For example, the first transmission filter 5TA and the second transmission filter 5TB may have the same transmission characteristic in a predetermined comparison band. A comparison band may be, for example, a transmission band and/or a reception band; a band consisting of a transmission band, a reception band, and a band therebetween (referred to as a transmission and reception band in the present paragraph); or a band centered on the center frequency of one of a transmission band, a reception band, and a transmission and reception band and having a width that is twice, three times, or five times the width of the one band. The first transmission filter 5TA and the second transmission filter 5TB may have the same delay time at any frequency in the comparison band (e.g., at the center frequency of the comparison band).

For certainty, a transmission characteristic is, for example, an S21 parameter when the input side of the transmission filter 5T is 1 and the output side of the transmission filter 5T is 2. A delay time is a delay of an output signal with respect to an input signal. The delay time can be converted to a phase using the periods (or frequencies) of signals (input signal and output signal). In a comparison of characteristics between two transmission filters 5T, characteristics at the same frequency are compared unless otherwise specified. When characteristics in a comparison band are the same, characteristics at the same frequency are the same over the entire comparison band. In another perspective, when a graph where the horizontal axis represents a frequency and the vertical axis represents a characteristic value is assumed, lines representing the characteristics of the two transmission filters 5T coincide. When characteristics are the same in the description of an embodiment, the term “characteristics” may be considered to refer to either all or some of various electrical characteristics (e.g., the transmission characteristic and the delay time described above), or may be considered to refer to characteristics at a specific frequency, in a specific frequency band, or at all frequencies, unless otherwise specified or unless there is a contradiction.

Even when characteristics are the same, they obviously do not need to be exactly the same. The degree of allowable difference may be reasonably determined in accordance with, for example, specifications required for the duplexer 1. For example, when two transmission filters 5T have the same transmission characteristic in a comparison band as described above, the range of being the same may include the case where, in part of or the entire comparison band, there is a difference of less than 5 dB between the transmission characteristics of the two transmission filters 5T. Also, for example, when two transmission filters 5T have the same delay time at any frequency in a comparison band as described above, the range of being the same may include the case where there is a difference of less than 5° in terms of phase between the two.

Unlike the configuration described above, the characteristics of the second transmission filter 5TB may differ from the characteristics of the first transmission filter 5TA. This is because if phases of a leakage signal and a cancellation signal are ideally opposite, a difference in strength between the two signals (i.e., signal strength after cancelling out) is smaller in varying degrees than the strength of the leakage signal, as long as the strength (assumed to be nonzero) of the cancellation signal is less than twice the strength of the leakage signal.

The description of the characteristics of the second transmission filter 5TB, in a comparison with the characteristics of the first transmission filter 5TA, is applicable to the characteristics of the second reception filter 5RB, for example, by replacing the term “first transmission filter 5TA” with the term “first reception filter 5RA” and replacing the term “second transmission filter 5TB” with the term “second reception filter 5RB”.

The characteristic of the transmission filter 5T exhibited when a signal is received on a side where a signal is assumed to be received (referred to as “assumed input side”, which is not necessarily a side where a signal is actually received) may be either the same as, or different from, the characteristic of the transmission filter 5T exhibited when a signal is received on a side where a signal is assumed to be output (referred to as “assumed output side”, which is not necessarily a side where a signal is actually output). In the latter case, for example, the characteristics of two transmission filters 5T exhibited when a signal is received on the assumed input side may be the same. Additionally, for example, the characteristics of the two transmission filters 5T exhibited when a signal is received on the assumed output side may also be the same. The above description of the transmission filter 5T applies to the reception filter 5R.

Assume that in the two transmission filters 5T, a characteristic exhibited when a signal is received on the assumed input side differs from a characteristic exhibited when a signal is received on the assumed output side, and that the characteristics of the two transmission filters 5T exhibited when a signal is received on the assumed input side are the same. In this case, for example, the first transmission filter 5TA may be connected on the assumed input side thereof to the side of the transmission terminal 3T and the second transmission filter 5TB may also be connected on the assumed input side thereof to the side of the transmission terminal 3T (or to the side of the node 17). This allows a signal from the transmission terminal 3T to pass through both of the two transmission filters 5T from the assumed input side.

Similarly, assume that in the two reception filters 5R, a characteristic exhibited when a signal is received on the assumed input side differs from a characteristic exhibited when a signal is received on the assumed output side, the characteristics of the two reception filters 5R exhibited when a signal is received on the assumed input side are the same, and the characteristics of the two reception filters 5R exhibited when a signal is received on the assumed output side are the same. In this case, for example, the first reception filter 5RA may be connected on the assumed input side thereof to the side of the antenna terminal 3A (in another perspective, to the side of the transmission terminal 3T), and the second reception filter 5RB may be connected on the assumed input side thereof to the side of the transmission terminal 3T. This allows a signal from the transmission terminal 3T to pass through both of the two reception filters 5R from the assumed input side.

For certainty, when a characteristic exhibited when a signal is received on the assumed input side is the same as a characteristic exhibited when a signal is received on the assumed output side, either the assumed input side or the assumed output side may be connected to the side of the transmission terminal 3T. Even in the case where a characteristic exhibited when a signal is received on the assumed input side differs from a characteristic exhibited when a signal is received on the assumed output side, two transmission filters 5T (and/or two reception filters 5R) do not need to be connected on the assumed input side thereof to the side of the transmission terminal 3T as described above, as can be understood from the above description stating that the characteristics of the two transmission filters 5T (and/or two reception filters 5R) do not necessarily need to be the same.

The filter 5 may have any of various configurations (structures) and may have, for example, a known configuration. Specifically, for example, the filter 5 may be a piezoelectric filter including a piezoelectric body, a dielectric filter using electromagnetic waves in a dielectric, an LC filter combining an inductor and a capacitor, or may be one obtained by combining two or more of those described above. The piezoelectric filter may be, for example, an acoustic wave filter using acoustic waves, or may be one not using acoustic waves (e.g., using a piezoelectric vibrator).

The acoustic wave filter may be any of various types, as long as it uses acoustic waves. For example, the acoustic wave filter may be one in which acoustic waves are excited by an interdigital transducer (IDT) electrode disposed on the surface of a piezoelectric body, or may be one in which acoustic waves are excited by electrodes facing each other, with a piezoelectric thin film therebetween (piezoelectric thin film resonator). For example, the acoustic wave filter may be a ladder filter in which a plurality of acoustic wave resonators are connected in a ladder form, a multi-mode filter (including a double mode filter) in which a plurality of IDT electrodes are arranged in the propagation direction of acoustic waves, or may be a transversal filter in which acoustic waves are transmitted and received between two IDT electrodes.

Acoustic waves are, for example, surface acoustic waves (SAWs), bulk acoustic waves (BAWs), boundary acoustic waves, or plate waves. These acoustic waves are not necessarily clearly distinguishable.

### 1.2. Phase Shifter

The phase shifter may have any of various configurations and may have, for example, a configuration same as and/or similar to a known configuration. For example, the phase shifter may be of distributed constant type, or may be of lumped constant type. A distributed-constant phase shifter is, for example, a transmission line having a length of λ/2, where λ represents the wavelength of a signal. The frequency of a signal used to calculate the wavelength λ may be, for example, the same as a frequency at which to compare the delay times described above. Specifically, for example, the frequency of the wavelength λ may be any frequency included in a transmission band, a reception band, and a band therebetween (e.g., the center frequency of the transmission band, the center frequency of the reception band, or the center frequency of the band between the transmission band and the reception band). The wavelength λ is a length measured when a signal propagates through the transmission line (phase shifter), and is influenced by the dielectric constant and the magnetic permeability of the transmission line (a broad concept including a dielectric therearound).

The phase shifter 9 simply needs to be capable of making a difference of 180° in terms of phase between the delay time of the first path RT1 and the delay time of the second path RT2. In other words, the phase shifter 9 simply needs to be capable of making the phases of output signals from the first path RT and the second path RT2, based on the same input signal to the two paths, opposite each other. The leakage signal and the cancellation signal can thus have opposite phases and can be at least partially cancelled out each other. The first path RT1 and the second path RT2 are made common on a side of the first branch point 19T closer to the transmission terminal 3T and on a side of the second branch point 19R closer to the reception terminal 3R. Therefore, the description above is also applicable to the delay times of two parallel paths from the first branch point 19T to the second branch point 19R.

As can be understood from above, the position of the phase shifter 9 is not limited to the illustrated one. For example, in an embodiment where the phase shifter 9 is configured to shift a phase by 180°, the phase shifter 9 may be disposed at any of the following four positions: a position between the first branch point 19T and the first transmission filter 5TA, a position between the first branch point 19T and the second reception filter 5RB, a position between the second branch point 19R and the first reception filter 5RA, and a position between the second branch point 19R and the second transmission filter 5TB (as in the illustrated example).

In summary, some or all positions of the phase shifter 9, described above, can be closer to the transmission terminal 3T (or the first branch point 19T, in another perspective) than the first transmission filter 5TA and the second reception filter 5RB are, and closer to the reception terminal 3R (or the second branch point 19R, in another perspective) than the first reception filter 5RA and the second transmission filter 5TB are. Unlike the embodiment described above, a part of or the entire phase shifter 9 may be disposed between the first transmission filter 5TA and the first reception filter 5RA (or in the first duplexer 7A, in another perspective), or between the second transmission filter 5TB and the second reception filter 5RB (or in the second duplexer 7B, in another perspective). Note, however, that the duplexer 1 can have better characteristics when the phase shifter 9 is disposed outside the duplexers 7 as in the embodiment.

Even when the phase shifter 9 is configured to shift a phase by 180° (or make phases opposite), the phase difference obviously does not need to be exactly 180°. The degree of allowable error may be reasonably determined in accordance with, for example, specifications required for the duplexer 1. For example, a phase difference of 180° (opposite phases) may include a phase difference of 180°+5°. A value obtained by converting the difference between the delay time of the first path RT1 and the delay time of the second path RT2 into a phase is not limited to 180°, and may be 360°×n+180°, where n is a relatively small integer equal to or greater than 1. The upper limit of n may be reasonably set in accordance with, for example, specifications required for the duplexer 1, and may be, for example, 1, 2, or 5.

### 1.3. Resistive Element

The resistive element 11 has a predetermined resistance value and connects the node 17 to the reference potential portion 13, as described above. For example, the resistance value of the resistive element 11 may be set to be the same as the absolute value of the characteristic impedance of the antenna terminal 3A. Generally, the absolute value of the characteristic impedance of the antenna terminal 3A is set to be approximately 50Ω in an intended frequency band. Accordingly, the resistance value of the resistive element 11 may be set to 50Ω.

The resistive element 11 may be a chip-type electronic component, or may be a conductor pattern formed on a circuit board. A circuit board on which the chip-type electronic component is mounted, or a circuit board on which the conductor pattern is formed may be, for example, one that is included in the duplexer 1, or may be a circuit board (not illustrated) on which the duplexer 1 is mounted. The circuit board included in the duplexer 1 is, for example, the multilayer substrate 21A illustrated in FIG. 2 or the multilayer substrate 21B illustrated in FIG. 4. Both the first exemplary structure and the second exemplary structure, described below, are examples in which the resistive element 11 is disposed outside the multilayer substrates 21A and 21B (outside the duplexer 1). The resistive element 11 may be included, for example, in the chip 23 illustrated in FIG. 2 or in the chip 25 illustrated in FIG. 4. Specifically, for example, the resistive element 11 may be constituted by a conductor formed on an upper surface of a piezoelectric substrate 35 described below.

The reference potential portion 13 to which the resistive element 11 (or parallel resonators 33P and the like, described below) is connected may be any of various conductors, as long as a reference potential is assumed to be applied thereto. The term “reference potential portion” may refer to all the various conductors described above or may refer to any of the various conductors, unless otherwise specified or unless there is a contradiction.

### 1.4. First Duplexer and Second Duplexer

As can be inferred from the above description of the filters 5, the first duplexer 7A and the second duplexer 7B may have the same characteristics. Such an example is an embodiment where the first duplexer 7A and the second duplexer 7B have the same structure. As can be inferred from the above description of the filters 5, the first duplexer 7A and the second duplexer 7B may have different characteristics, as long as a strength measured after the cancellation signal and the leakage signal are cancelled out is smaller than the strength of the leakage signal.

The above description about the fact that two filters 5 have the same characteristics is applicable to the fact that the first duplexer 7A and the second duplexer 7B have the same characteristics. For example, not all the various characteristics of the two duplexers 7 need to be the same in various frequency bands. That is, transmission characteristics in the comparison band described above may be the same, and the delay times at any frequency in the comparison band may be the same. Even when characteristics are the same, they do not need to be exactly the same. For example, a difference of less than 5 dB in transmission characteristic, and a difference of less than 5° in delay time in terms of phase may be included in the range of being the same.

When two duplexers 7 have the same characteristics, first, the characteristics of signal passage may be compared between each filter 5 in one duplexer 7 and the corresponding filter 5 in the other duplexer 7. For example, a characteristic exhibited when a signal flows through the first transmission filter 5TA from the transmission terminal 3T toward the antenna terminal 3A may be compared with a characteristic exhibited when a signal flows through the second transmission filter 5TB from the reception terminal 3R toward the node 17. Similarly, a characteristic exhibited when a signal flows through the first reception filter 5RA from the antenna terminal 3A toward the reception terminal 3R may be compared with a characteristic exhibited when a signal flows through the second reception filter 5RB from the node 17 toward the transmission terminal 3T. Characteristics exhibited when a signal flows through each of the filters 5 in other directions may be compared.

In addition to, or in place of, the example described above, characteristics may be compared between combinations of two filters. For example, a characteristic exhibited when a signal flows through the first transmission filter 5TA and the first reception filter 5RA in sequence may be compared with a characteristic exhibited when a signal flows through the second transmission filter 5TB and the second reception filter 5RB in sequence. Then, the characteristics here may be determined to be the same for the two duplexers 7. Since the leakage signal and the cancellation signal flow from the transmission terminal 3T to the reception terminal 3R, a characteristic exhibited when a signal flows through the first transmission filter 5TA and the first reception filter 5RA in sequence may be compared with a characteristic exhibited when a signal flows through the second reception filter 5RB and the second transmission filter 5TB in sequence. Then, the characteristics here may be determined to be the same for the two duplexers 7.

A characteristic exhibited when a signal flows through the first transmission filter 5TA and the first reception filter 5RA in sequence may either be the same as, or different from, a characteristic exhibited when a signal flows in the direction opposite that described above. The same applies to the second transmission filter 5TB and the second reception filter 5RB.

As can be understood from the above description of the filters 5, a connection relationship between the assumed input side and the assumed output side of the first transmission filter 5TA and the assumed input side and the assumed output side of the first reception filter 5RA may either be the same as, or different from, a positional relationship between the assumed input side and the assumed output side of the second transmission filter 5TB and the assumed input side and the assumed output side of the second reception filter 5RB.

For example, as illustrated in the above description of the filters 5, when the assumed input sides of all the four filters 5 are on the side of the transmission terminal 3T, the assumed output side of the first transmission filter 5TA is connected to the assumed input side of the first reception filter 5RA in the first duplexer 7A, and the assumed input side of the second transmission filter 5TB is connected to the assumed output side of the second reception filter 5RB in the second duplexer 7B. That is, a connection relationship between the assumed input side and the assumed output side of the transmission filter 5T and the assumed input side and the assumed output side of the reception filter 5R differs between the first duplexer 7A and the second duplexer 7B. This connection relationship will also be referred to in the description of the first exemplary structure.

Examples of an embodiment where the first duplexer 7A and the second duplexer 7B have the same connection relationship include an embodiment where the assumed output side of the first transmission filter 5TA is connected to the assumed input side of the first reception filter 5RA in the first duplexer 7A, and the assumed output side of the second transmission filter 5TB is also connected to the assumed input side of the second reception filter 5RB in the second duplexer 7B. This connection relationship will also be referred to in the description of the second exemplary structure.

### 2. Exemplary Structures of Duplexer

The duplexer 1 may be configured, for example, as a chip-type electronic component that only functions as a duplexer. The duplexer 1 may be inseparably combined with an element having a function different from that of a duplexer, and the electronic component including the duplexer 1 does not necessarily need to be of a chip type. For example, while not specifically illustrated, in a module substrate including a circuit board, an integrated circuit (IC) mounted on or included in the circuit board, an antenna mounted on or included in the circuit board, and the duplexer 1, a part of or the entire duplexer 1 may be included in the circuit board.

In the description of the first exemplary structure and the second exemplary structure below, a chip-type electronic component functioning only as a duplexer will be illustrated as the duplexer 1.

### 2.1. First Exemplary Structure

### 2.1.1. Overall Configuration of Duplexer

FIG. 2 is a schematic perspective view illustrating a main part of the configuration of a duplexer 1A, which is an example of the duplexer 1.

In this drawing, the chips 23 are indicated by a dotted line and the upper surface of the multilayer substrate 21A is visible. Wiring lines in the multilayer substrate 21A are schematically illustrated. Either direction of the duplexer 1A may be defined as an upward (or downward) direction. In the description of FIG. 2, for convenience, a rectangular coordinate system xyz is defined, and the +z side is defined as the upper side. Such terms as an upper surface and a lower surface may thus be used accordingly (the same applies to FIG. 4 illustrating the second exemplary structure described below).

The duplexer 1A is configured, for example, as a surface-mount, chip-type electronic component. For example, the duplexer 1A includes a plurality of terminals 3 (external terminals) each constituted by a layer-like conductor disposed on the lower surface. The plurality of terminals 3 face pads disposed on the upper surface of a circuit board (not illustrated), and are bonded to the pads by a conductive bonding material interposed therebetween. In another perspective, the conductive bonding material is a bump, which is made of, for example, solder (the same applies hereinafter). The duplexer 1A has any general shape and dimensions. For example, the entire duplexer 1A is substantially in the shape of a thin rectangular parallelepiped.

The plurality of terminals 3 include, as described above, the antenna terminal 3A, the transmission terminal 3T, and the reception terminal 3R. In the illustrated example, the plurality of terminals 3 include a resistor terminal 3B connected to the resistive element 11. The resistive element 11 is disposed on a circuit board (not illustrated) on which the duplexer 1A is mounted. Although not specifically illustrated, the plurality of terminals 3 may include a reference potential terminal to which a reference potential is applied from the circuit board. The number, positions, shape, and dimensions of the plurality of terminals 3 may be appropriately set.

The duplexer 1A configured as a chip-type electronic component is not limited to one that includes the layer-like terminals 3 on the lower surface thereof. For example, the layer-like terminal 3 on the upper surface may be connected by bonding wires to a circuit board (not illustrated). Also, for example, the terminals 3 having a pin shape may be bonded to the multilayer substrate 21A.

As described above, the duplexer 1A includes, for example, the multilayer substrate 21A and one or more chips 23 (four chips 23 in the illustrated example) mounted on the multilayer substrate 21A. In the illustrated example, each chip 23 includes one filter 5, and the duplexer 1A includes four chips 23 corresponding to four filters 5. The four chips 23 may be disposed at any positions on the upper surface of the multilayer substrate 21A, and may be disposed at any relative positions. The duplexer 1A may include components not illustrated in the drawings. Examples of such components include a sealing material and a cover covering the upper surface of the multilayer substrate 21A from above the chips 23.

### 2.1.2. Multilayer Substrate

The basic structure and material of the multilayer substrate 21A (circuit board) (excluding a specific conductor pattern and dimensions and the like for forming the duplexer 1A) may be the same as and/or similar to the structure and material of any of various known printed boards. For example, the multilayer substrate 21A may be a low temperature co-fired ceramics (LTCC) substrate, a high temperature co-fired ceramic (HTCC) substrate, an integrated passive device (IPD) substrate, or an organic substrate.

Examples of the LTCC substrate include one that is made by adding a glass-based material to alumina and capable of being fired at low temperatures (e.g., around 900° C.). In the LTCC substrate, a conductive material, such as Cu or Ag, may be used. Examples of the HTCC substrate include one that is made of ceramic mainly composed of alumina or aluminum nitride. In the HTCC substrate, a conductive material, such as tungsten or molybdenum, may be used. Examples of the IPD substrate include one that is produced by forming a passive element on an Si substrate. Examples of the organic substrate include one that is a laminate of prepreg layers produced by impregnating a base material made of glass or the like with resin.

The multilayer substrate 21A includes an insulating base member 22 and a conductor 27 disposed inside and/or on the surface of the base member 22. As can be understood from the description in the previous paragraph, the base member 22 and the conductor 27 are made of any materials. The base member 22 may include, for example, a laminate of insulating layers 22a. The base member 22 may have any shape and dimensions. In the illustrated example, the base member 22 is in the shape of a thin rectangular parallelepiped. The conductor 27 may include, for example, a conductor layer disposed on the upper surface or the lower surface (main surface) of the insulating layers 22a, and via conductors penetrating the insulating layers 22a. The numbers, positions, shapes, and dimensions of the conductor layers and the via conductors may be appropriately set in accordance with functions or the like required for the multilayer substrate 21A.

FIG. 2 illustrates, as examples of the conductor 27 (conductor layer), the plurality of (or some of the plurality of) terminals 3 described above and a plurality of (or some of the plurality of) pads 29 (29I and 29O) for mounting the chips 23 on the multilayer substrate 21A. As described below, the plurality of terminals 3 and the plurality of pads 29 are connected, for example, through the conductor 27 included in the multilayer substrate 21A. This allows the filter 5 included in each chip 23 to filter a signal received at any terminal 3 and output the resulting signal to another terminal 3.

The plurality of pads 29 are disposed, for example, on the upper surface of the base member 22. For example, the plurality of pads 29 face a layer-like external terminal (not illustrated) disposed on the lower surface of each chip 23, and are bonded to the layer-like external terminal, with a conductive bonding material (not illustrated) interposed therebetween. The chips 23 are thus surface-mounted on the multilayer substrate 21A. Unlike the illustrated example, the pads 29 may be electrically connected by a bonding wire to an external terminal disposed on the upper surface of each chip 23.

The number, positions, shape, dimensions, and the like of the plurality of pads 29 may be appropriately set in accordance with the number of one or more chips 23 and the number, positions, shape, dimensions, and the like of terminals (not illustrated in FIG. 2) on each chip 23. Normally, at least four pads 29 are provided to be capable of supporting at least four corners of each chip 23. The plurality of pads 29 include, for example, a pad for receiving a signal at the chip 23 (filter 5), a pad for outputting a signal form the chip 23, and a pad for applying a reference potential to the chip 23.

### 2.1.3. Chip

As described above, the filter 5 included in each chip 23 may have any of various configurations. Here, a ladder filter will be described as an example of the filter 5. A ladder filter is a filter in which acoustic wave resonators using IDT electrodes are connected in a ladder form.

FIG. 3 is a schematic plan view illustrating the chip 23 as viewed from the multilayer substrate 21A.

Either direction of the chip 23 may be defined as an upward (or downward) direction. In the description of FIG. 3, for convenience, a rectangular coordinate system consisting of a D1 axis, a D2 axis, and a D3 axis is added to the drawing and the term, such as an upper surface or a lower surface, may be used, with the +D3 side being the upper side. The D1 axis is defined to be parallel to the propagation direction of acoustic waves propagating along the upper surface of a piezoelectric body (described below), the D2 axis is defined to be parallel to the upper surface of the piezoelectric body and orthogonal to the D1 axis, and the D3 axis is defined to be orthogonal to the upper surface of the piezoelectric body.

Of signals received at an input terminal 31I, those having frequencies within a predetermined passband are output to an output terminal 31O by the filter 5. Signals having frequencies outside the passband are released to a GND terminal 31G connected to the reference potential portion. These terminals may be collectively referred to as terminals 31. Any number of terminals 31 having any shape, dimensions, and the like may be disposed at any positions on the upper surface of the chip 23.

The filter 5 includes a plurality of resonators 33 (33S and 33P) connected in a ladder form. That is, the filter 5 includes a plurality of (or one) series resonators 33S connected in series between the input terminal 31I and the output terminal 31O, and a plurality of (or one) parallel resonators 33P (parallel arms) connected in parallel between the series line (series arm) and the GND terminal 31G (reference potential portion). Each parallel resonator 33P is connected to a side of one of the series resonators 33S closer to either the input terminal 31I or the output terminal 31O. That is, the plurality of parallel resonators 33P connect a plurality of electrically different positions in the series arm to the GND terminal 31G. Any number of series resonators 33S and any number of parallel resonators 33P may be disposed at any positions on the upper surface of the chip 23.

Each resonator 33 is constituted by a so-called one-port acoustic wave resonator. The resonator 33 includes, for example, the piezoelectric substrate 35 (or part of at least the upper surface side thereof), the IDT electrode 37 (or an excitation electrode in a broader concept) disposed on the upper surface of the piezoelectric substrate 35, and a pair of reflectors 39 disposed on both sides of the IDT electrode 37. The piezoelectric substrate 35 is shared by the plurality of resonators 33. In the description of an embodiment, for distinction among the plurality of resonators 33 sharing the same piezoelectric substrate 35, a combination of the IDT electrode 37 and the pair of reflectors 39 (i.e., an electrode portion of the resonator 33) may be expressed as the resonator 33 (i.e., the resonator 33 may be expressed as if it does not include the piezoelectric substrate 35) for convenience.

The piezoelectric substrate 35 has piezoelectricity at least in regions of the upper surface thereof where the resonators 33 are provided. An example of the piezoelectric substrate 35 is one in which the entire substrate is constituted by a piezoelectric body. Another example of the piezoelectric substrate 35 is a so-called bonded substrate. A bonded substrate includes a substrate (piezoelectric substrate) constituted by a piezoelectric body, and a support substrate bonded to the lower surface of the piezoelectric substrate with an adhesive therebetween, or bonded directly to the lower surface of the piezoelectric substrate without an adhesive therebetween. The support substrate may include a cavity below the piezoelectric substrate, or may include no cavity. Examples of the piezoelectric substrate 35 also include one that includes a support substrate and, on part of or the entire upper surface of the support substrate, a film constituted by a piezoelectric body (piezoelectric film) or a plurality of films including a piezoelectric film. Materials of the piezoelectric body may be known materials, such as lithium tantalate (LiTaO₃), lithium niobate (LiNbO₃), and quartz crystal (SiO₂).

The IDT electrode 37 and the reflectors 39 are constituted by a layer-like conductor disposed on the piezoelectric substrate 35. The IDT electrode 37 includes a pair of comb-like electrodes (not denoted by reference numerals) that are arranged in such a way as to engage with each other. The pair of reflectors 39 is disposed on both sides of the IDT electrode 37 in the propagation direction of acoustic waves. The reflectors 39 are formed, for example, in a lattice pattern. Each reflector 39 may be, for example, in an electrically floating state, or may be provided with a reference potential. The shapes, dimensions, and materials of the IDT electrode 37 and the reflectors 39 may be any of various ones and may be, for example, the same as and/or similar to known ones.

Application of a voltage to the IDT electrode 37 excites acoustic waves propagating in the D1 direction. Acoustic waves propagating in the D1 direction are converted by the IDT electrode 37 to electrical signals. At this point, the function of the resonator is implemented by an action, such as increasing the amplitude of acoustic waves having a specific frequency corresponding to the pitch of a plurality of electrode fingers (teeth) of the IDT electrode 37. The pair of reflectors 39 contributes to confining acoustic waves.

Although not specifically illustrated, the impedance of each resonator 33 is minimized at the resonance frequency and maximized at the antiresonance frequency. The resonance frequencies of the plurality of series resonators 33S are set to be substantially the same, and the antiresonance frequencies of the plurality of series resonators 33S are set to be substantially the same. The resonance frequencies of the plurality of parallel resonators 33P are set to be substantially the same, and the antiresonance frequencies of the plurality of parallel resonators 33P are set to be substantially the same. The resonance frequency of the series resonators 33S is set to be substantially the same as the antiresonance frequency of the parallel resonators 33P.

A bandpass filter is implemented by setting resonance and antiresonance frequencies, such as those described above. The center frequency of a passband is substantially the same as the resonance frequency of the series resonators 33S and the antiresonance frequency of the parallel resonators 33P. The width of the passband is slightly narrower than the width from the resonance frequency of the parallel resonators 33P to the antiresonance frequency of the series resonators 33S.

For example, the chip 23 may be mostly constituted by the piezoelectric substrate 35. Specifically, for example, the chip 23 may include the piezoelectric substrate 35 and a relatively thin layer disposed over the surface of the piezoelectric substrate 35. Examples of the relatively thin layer include a conductive layer (e.g., IDT electrode 37) disposed over the upper surface of the piezoelectric substrate 35, and an insulating protective film covering the majority of the upper surface of the piezoelectric substrate 35 (e.g., region excluding the terminals 31) from above the conductive layer. The chip 23 may include a layer covering the side surface or the lower surface of the piezoelectric substrate 35.

For example, the chip 23 configured as described in the previous paragraph is mounted on the multilayer substrate 21A, with the surface on the +D3 side facing the upper surface of the multilayer substrate 21A (i.e., the surface on the upper side in FIG. 2). Here, the terminals 31 on the chip 23 and the pads 29 on the multilayer substrate 21A face each other and are bonded by a conductive bonding material (not illustrated) interposed therebetween. Between the chip 23 and the multilayer substrate 21 (or on the resonators 33 in another perspective), a space is created which has a height substantially equivalent to the thickness of the bonding material for bonding the terminals 31 to the pads 29.

Although not specifically illustrated, for example, the chip 23 may include, as well as the components described above, a box-shaped insulating cover covering the upper surface of the piezoelectric substrate 35. The cover creates a space above the resonators 33. The chip 23 includes, for example, columnar terminals disposed on the terminals 31 and penetrating the cover. The chip 23 is mounted on the multilayer substrate 21A, with the surface of the cover on the +D3 side facing the upper surface of the multilayer substrate 21 (i.e., the surface on the upper side in FIG. 2). Here, the upper surface of the columnar terminal and the corresponding pad 29 on the multilayer substrate 21A face each other and are bonded by a conductive bonding material (not illustrated) interposed therebetween.

### 2.1.4. Exemplary Structure of Connection

As described above, in plan view (when the upper surface of the multilayer substrate 21A is viewed), the four filters 5 may be disposed at any relative positions, the terminals 31 (31I, 31O, and 31G) may be disposed at any positions in each filter 5, and the terminals 3 (3A, 3B, 3T, 3R, and the terminal 3 for reference potential (not illustrated)) may also be disposed at any positions in the multilayer substrate 21A. The conductor 27 of the multilayer substrate 21A connecting the plurality of terminals 31 and the plurality of terminals 3 may also have any structure, as long as the circuit configuration described with reference to FIG. 1 is implemented. FIG. 2 illustrates an exemplary connection in which in an embodiment where two transmission filters 5T have the same configuration and two reception filters 5R have the same configuration, the two transmission filters 5T are both connected on the assumed input side thereof to the side of the transmission terminal 3T (left side in FIG. 1) and the two reception filters 5R are both connected on the assumed input side thereof to the side of the transmission terminal 3T (left side in FIG. 1).

In FIG. 2, the pad 29 connected to the terminal 31 (FIG. 3) on the assumed input side of the filter 5 is denoted by reference numeral 29I, and the pad 29 connected to the terminal 31 on the assumed output side of the filter 5 is denoted by reference numeral 29O. In FIG. 2, four filters 5 are arranged clockwise in the following order: the first transmission filter 5TA, the first reception filter 5RA, the second transmission filter 5TB, and the second reception filter 5RB. This arrangement can be considered the same as the arrangement of the four filters 5 in the plane of FIG. 1 (the +y side is considered the upper side along the plane in FIG. 1).

In each of the filters 5, the pads 29I and 29O are located at a pair of diagonally opposite corners of the filter 5. In each of the transmission filters 5T, the pad 29I is located on the-x side and the −y side, and the pad 29O is located on the +x side and the +y side. In each of the reception filters 5R, the pad 29I is located on the −x side and the +y side, and the pad 29O is located on the +x side and the −y side.

In the arrangement described above, two pads 29 connected to each other are located at two opposite corners adjacent to each other of two chips including the two pads 29. This can simplify the configuration of the wiring line (conductor 27) of the multilayer substrate 21A connecting the two pads 29. As described above, the wiring line illustrated in FIG. 2 is schematic one. As can be seen from FIG. 2, however, the wiring line may include, for example, two via conductors having substantially the same shape and dimensions and extending downward from two pads 29, and a conductor layer (conductor pattern) connecting the two via conductors. For example, the conductor pattern may linearly extend with a constant width.

### 2.1.5. Exemplary Configuration of Phase Shifter

In FIG. 2, the phase shifter 9 is constituted by a transmission line having a length of λ/2. In FIG. 2, for convenience, the transmission line constituting the phase shifter 9 is represented by a thick line to distinguish from other wiring lines. The transmission line constituting the phase shifter 9 may have any cross-sectional area and may have, for example, the same cross-sectional area as the other wiring lines. Like FIG. 1, FIG. 2 illustrates an embodiment in which the phase shifter 9 is disposed between the second transmission filter 5TB and the second branch point 19R. The description here may be given on the basis of this embodiment without particularly stated.

As schematically illustrated in FIG. 2, the wiring line connecting the first transmission filter 5TA to the first reception filter 5RA and the wiring line connecting the second transmission filter 5TB to the second reception filter 5RB may have the same length. The wiring line connecting the first transmission filter 5TA to the first branch point 19T and the wiring line connecting the second reception filter 5RB to the first branch point 19T may have the same length. On the other hand, the wiring line connecting the second transmission filter 5TB to the second branch point 19R (i.e., the wiring line including the phase shifter 9) may be λ/2 longer than the wiring line connecting the first reception filter 5RA to the second branch point 19R. This can achieve a phase difference of 180°. The same can apply to the cases where a λ/2 transmission line is provided at three other positions.

FIG. 2 illustrates the 2/2 transmission line in such a way as to represent a conductor layer (conductor pattern) linearly extending with a constant width. The λ/2 transmission line may actually have such a configuration, or may be configured differently. For example, the λ/2 transmission line may include a via conductor, or may include a conductor pattern that extends while appropriately bending.

### 2.2. Second Exemplary Structure

In the description of the second exemplary structure, differences from the first exemplary structure alone will be basically described. Matters not specifically mentioned may be considered the same as and/or similar to the first exemplary structure, or may be inferred from the first exemplary structure.

FIG. 4 is a schematic perspective view illustrating a main part of the configuration of a duplexer 1B, which is an example of the duplexer 1. FIG. 4 corresponds to FIG. 2 illustrating the first exemplary structure.

Generally, the duplexer 1B of the second exemplary structure differs from the duplexer 1A of the first exemplary structure in that each filter 5 does not constitute the chip 23, but each duplexer 7 constitutes the chip 25. This is specifically as follows.

The duplexer 1B includes the multilayer substrate 21B and two chips 25 mounted on the multilayer substrate 21B. Like the multilayer substrate 21A of the first exemplary structure, the multilayer substrate 21B includes a plurality of terminals 3 disposed on the lower surface thereof. The plurality of terminals 3 include, for example, the antenna terminal 3A, the transmission terminal 3T, the reception terminal 3R, the resistor terminal 3B, and the reference potential terminal (not illustrated), like the plurality of terminals 3 of the first exemplary structure.

Like the multilayer substrate 21A of the first exemplary structure, the multilayer substrate 21B includes a plurality of pads 29 on which the chips 25 are mounted. The number, positions, functions, and the like of the plurality of pads 29 differ from those of the plurality of pads 29 of the first exemplary structure, in accordance with differences between the chips 25 and the chips 23 of the first exemplary structure 1. For example, the plurality of pads 29 of the second exemplary structure include, for each chip 25, at least four pads 29 (only three of them are illustrated) connected to the antenna terminal 3A (or resistor terminal 3B), the transmission terminal 3T, the reception terminal 3R, and the terminal 3 for reference potential (not illustrated). For example, the plurality of pads 29 may be provided to be capable of supporting four corners of the chip 25.

FIG. 5 is a schematic plan view illustrating the chip 25 as viewed from the multilayer substrate 21B. This drawing corresponds to FIG. 3 illustrating the first exemplary structure. For convenience, FIG. 5 is more schematic than FIG. 3. Specifically, the IDT electrode 37 and the reflectors 39 are represented by rectangles in FIG. 5.

The filters 5 included in the duplexer 7 may have any of various configurations, as described above. Here, a ladder filter same as and/or similar to the first exemplary structure is used as an example. The duplexer 7 includes the transmission filter 5T and the reception filter 5R. These filters 5 are basically the same as and/or similar to the filter 5 constituting the chip 23 of the first exemplary structure, except that the piezoelectric substrate 35 is shared by the transmission filter 5T and the reception filter 5R.

Assume, for convenience, that the first duplexer 7A of the two duplexers 7 is illustrated in FIG. 5. The chip 25 includes a terminal 31A connected to the antenna terminal 3A, a terminal 31T connected to the transmission terminal 3T, a terminal 31R connected to the reception terminal 3R, and the GND terminal 31G connected to the terminal 3 for reference potential (not illustrated). The plurality of series resonators 33S of the transmission filter 5T are connected in series between the terminal 31 A and the terminal 31T. The plurality of series resonators 33S of the reception filter 5R are connected in series between the terminal 31A and the terminal 31R. The various terminals may be disposed at any positions, and the various resonators 33 may be disposed at any positions on the upper surface of the chip 25.

Referring back to FIG. 4, in plan view (when the upper surface of the multilayer substrate 21B is viewed), two duplexers 7 (chips 25) may be disposed at any relative positions, the terminals 31 may be disposed at any positions in each chip 25, and the terminals 3 may be disposed at any positions in the multilayer substrate 21B. The conductor 27 of the multilayer substrate 21B connecting the plurality of terminals 31 and the plurality of terminals 3 may also have any structure, as long as the circuit configuration described with reference to FIG. 1 is implemented. FIG. 4 illustrates an exemplary connection in an embodiment where two duplexers 7 (chips 25) have the same configuration.

In FIG. 4, three types of pads 29 connected to the terminals 31A, 31T, and 31R (see FIG. 5) are denoted by reference numerals 29A, 29T, and 29R. In the first duplexer 7A, the terminals 31A, 31T, and 31R are terminals connected to the antenna terminal 3A, the transmission terminal 3T, and the reception terminal 3R, as described above. The terminals 31A, 31T, and 31R in the second duplexer 7B are terminals assumed to be connected to the antenna terminal 3A, the transmission terminal 3T, and the reception terminal 3R if the second duplexer 7B is used as the first duplexer 7A.

As can be understood from the positions of the pads 29T and 29R, the terminals 31T and 31R are arranged along one side of each chip 25. In plan view, two chips 25 are disposed such that their sides along which the terminals 31T and 31R are arranged face each other. In another perspective, the two chips 25 are disposed in opposite orientations in plan view. The terminals 31A of the two chips 25 (see the positions of the pads 29A) are arranged at 180° rotationally symmetrical positions with respect to the center between the two chips 25.

In the arrangement described above, two pads 29 connected to each other are adjacent to each other. That is, the pad 29T for the first duplexer 7A and the pad 29R for the second duplexer 7B are adjacent, and the pad 29R for the first duplexer 7A and the pad 29T for the second duplexer 7B are adjacent. This can simplify the configuration of the wiring line (conductor 27) of the multilayer substrate 21B connecting the two pads 29. The wiring line illustrated in FIG. 4 is schematic one. As can be seen from FIG. 4, however, the wiring line connecting the pads 29 may include, for example, two via conductors having substantially the same shape and dimensions and extending downward from the two pads 29, and a conductor layer (conductor pattern) connecting the two via conductors.

The arrangement in which, as in FIG. 4, the second duplexer 7B is placed adjacent to and in an orientation opposite the first duplexer 7A in plan view may be applied to an arrangement of the pads 29A, 29T, and 29R different from the illustrated example. For example, two pads 29 connected to each other do not necessarily need to be adjacent to each other. Even in this case, since the positions of two pads 29 connected to each other are aligned in the x direction, the configuration of wiring lines of the multilayer substrate 21B can be simplified.

In FIG. 4, as in the first exemplary structure, the phase shifter 9 is constituted by a 22 transmission line disposed between the second branch point 19R and the second transmission filter 5TB. Specifically, for example, as schematically illustrated in FIG. 4, the wiring line connecting the pad 29T for the first duplexer 7A (or the pad 29 connected to the first transmission filter 5TA) to the first branch point 19T, and the wiring line connecting the pad 29R for the second duplexer 7B (or the pad 29 connected to the second reception filter 5RB) to the first branch point 19T have the same length. On the other hand, the wiring line connecting the pad 29T for the second duplexer 7B (or the pad 29 connected to the second transmission filter 5TB) to the second branch point 19R may be λ/2 longer than the wiring line connecting the pad 29R for the first duplexer 7A (or the pad 29 connected to the first reception filter 5RA) to the second branch point 19R.

### 2.3. Other Exemplary Structures

Although the correspondence relationship between filters and chips will not be specifically illustrated, embodiments other than the first exemplary structure and the second exemplary structure are possible. For example, the four filters 5 may all be provided on the same be chip (or on the same piezoelectric substrate 35, in another perspective). One of the two duplexers 7 (e.g., first duplexer 7A) may be constituted by one chip 25, and the other duplexer (e.g., second duplexer 7B) may be constituted by two chips 23. The first transmission filter 5TA and the second transmission filter 5TB may be provided on the same chip (or on the same piezoelectric substrate 35), and the first reception filter 5RA and the second reception filter 5RB may be provided on the same chip (or on the same piezoelectric substrate 35).

### 2.4. Exemplary Structure of Node

As described above, the resistive element 11 may or may not be included in the duplexer 1 (or may be externally attached to the duplexer 1). Therefore, when features related to the connection to the resistive element 11 are extracted by taking both embodiments into consideration (in another perspective, when a determination as to whether to apply the technique according to the present disclosure is made by focusing only on the duplexer 1 not including the resistive element 11), attention may be focused on the node 17. The node 17 may have any of various configurations corresponding to various structures of the duplexer 1.

In the first exemplary structure, as illustrated in FIG. 2, the node 17 is disposed in the multilayer substrate 21A. Specifically, the node 17 is a point where the wiring line extending from the pad 29I for the second transmission filter 5TB and the wiring line extending from the pad 29O for the second reception filter 5RB are joined. Specifically, although the wiring line illustrated in FIG. 2 is schematic one, it can be considered as a representation of an embodiment where the node 17 is formed by a point of connection between the conductor layer and the via conductors. Unlike the configuration described above, for example, the node 17 may be formed by joining wiring lines constituted by three conductor layers. Also, for example, the wiring line extending from the pad 29I for the second transmission filter 5TB and the wiring line extending from the pad 29O for the second reception filter 5RB may individually reach the resistor terminal 3B, and the resistor terminal 3B may constitute the node 17.

In the second exemplary structure, when the chip 25 illustrated in FIG. 5 is considered as one that constitutes the second duplexer 7B, the node 17 is provided in the chip 25 while it is not denoted by a reference numeral in FIG. 5. Specifically, the node 17 is a point where the wiring line extending from the transmission filter 5T to the terminal 31A and the wiring line extending from the reception filter 5R to the terminal 31A are joined. Unlike the illustrated example, the wiring line extending from the transmission filter 5T to the terminal 31A and the wiring line extending from the reception filter 5R to the terminal 31A may individually reach the terminal 31A, and the terminal 31A may constitute the node 17.

As described above, the node 17 may have any of various configurations. A determination as to whether the node 17 connected to, or connectable to, the resistive element 11 is provided may be reasonably made on the basis of common technological knowledge and the like. Typically, as can be understood from the examples described above, the node 17 is a point where three wiring lines are joined, or a terminal where two wiring lines are individually joined. The point where three wiring lines are joined can be considered as a branch point. The terminal where two wiring lines are joined is connected to another device (or another wiring line, in another perspective), and thus can be considered as a branch point. Therefore, the node 17 can be considered to be located at a branch point. One connection destination from the branch point is the resistive element 11, or a terminal or the like connectable to a device outside the duplexer 1.

### 3. Communication Apparatus including Duplexer

FIG. 6 is a block diagram illustrating a main part of a communication apparatus 151 which is an exemplary application of the duplexer 1. The communication apparatus 151 includes a module 171 and a housing 173 containing the module 171. The module 171 is configured to perform radio communication using radio waves and includes the duplexer 1. Here, only the first transmission filter 5TA and the first reception filter 5RA of the duplexer 1 are schematically illustrated.

In the module 171, a transmission information signal TIS containing information to be transmitted is turned into a transmission signal TS by being modulated and raised in frequency (i.e., converted to a radio-frequency signal having a carrier frequency) by a radio frequency integrated circuit (RF-IC) 153 (which is an example of an integrated circuit element). A bandpass filter 155 eliminates unwanted components of the transmission signal TS outside a transmission passband. The transmission signal TS is then amplified by an amplifier 157 and received by the duplexer 1 (transmission terminal 3T). The duplexer 1 (first transmission filter 5TA) eliminates unwanted components of the received transmission signal TS outside the transmission passband, and outputs the resulting transmission signal TS from the antenna terminal 3A to an antenna 159. The antenna 159 converts the received electrical signal (transmission signal TS) to a radio signal (radio wave) and transmits it.

In the module 171, a radio signal (radio wave) received by the antenna 159 is converted by the antenna 159 to an electrical signal (reception signal RS) and received by the duplexer 1 (antenna terminal 3A). The duplexer 1 (first reception filter 5RA) eliminates unwanted components of the received reception signal RS outside a reception passband and outputs the resulting reception signal RS from the reception terminal 3R to an amplifier 161. The amplifier 161 amplifies the received reception signal RS, and a bandpass filter 163 eliminates unwanted components of the reception signal RS outside the reception passband. The reception signal RS is turned into a reception information signal RIS by being lowered in frequency and demodulated by the RF-IC 153.

The transmission information signal TIS and the reception information signal RIS may be low frequency signals (baseband signals) containing appropriate information, such as analog audio signals or digital audio signals. A passband of radio signals may be appropriately set. The modulation method may be phase modulation, amplitude modulation, frequency modulation, or a combination of two or more of these. Although a direct conversion system is illustrated as a circuit system, any other appropriate circuit system, such as a double-superheterodyne system, may be used. FIG. 6 schematically illustrates only a main part. A low-pass filter, an isolator, and the like may be added at appropriate positions, and the positions of the amplifiers and the like may be changed.

In the module 171, for example, components arranged in order from the RF-IC 153 to the antenna 159 are mounted on or included in the same circuit board. The duplexer 1 is thus combined with other components and turned into a module. The duplexer 1 may be included in the communication apparatus 151 without being turned into a module. Components illustrated as components of the module 171 may be disposed outside the module, or do not need to be contained in the housing 173. For example, the antenna 159 may be exposed to the outside of the housing 173.

### 4. Summary of Embodiments

As described above, a branching filter (duplexer 1) includes a first filter (first transmission filter 5TA), a second filter (first reception filter 5RA), a third filter (second transmission filter 5TB), a fourth filter (second reception filter 5RB), and a 180° phase shifter (phase shifter 9). The first transmission filter 5TA is configured to connect a common terminal (antenna terminal 3A) to a first terminal (transmission terminal 3T), and corresponds to a first passband (transmission band) (i.e., configured to allow signals in the transmission band to pass through). The first reception filter 5RA is configured to connect the antenna terminal 3A to a second terminal (reception terminal 3R), and corresponds to a second passband (reception band) not overlapping the transmission band (i.e., configured to allow signals in the reception band to pass through). The second transmission filter 5TB is configured to connect the node 17 disposed at a branch point to the reception terminal 3R, and corresponds to the transmission band. The second reception filter 5RB is configured to connect the node 17 to the transmission terminal 3T, and corresponds to the reception band. The phase shifter 9 is disposed closer to the transmission terminal 3T than the first transmission filter 5TA and the second reception filter 5RB are, or disposed closer to the reception terminal 3R than the first reception filter 5TB and the second transmission filter 5TB are. The phase shifter 9 is configured to make phases of output signals from a path (first path RT1) extending from the transmission terminal 3T through the first transmission filter 5TA and the first reception filter 5RA to the reception terminal 3R and a path (second path RT2) extending from the transmission terminal 3T through the second reception filter 5RB and the second transmission filter 5TB to the reception terminal 3R opposite each other. The output signals are based on the same input signal to the paths.

Thus, as described above, a leakage signal and a cancellation signal can be cancelled out, and isolation characteristics can be improved. Since the phase shifter 9 is not disposed between the first transmission filter 5TA and the first reception filter 5RA and between the second transmission filter 5TB and the second reception filter 5RB, for example, a probability that unintended standing waves will be produced by the phase shifter 9 is reduced. Also, for example, when the first duplexer 7A and the second duplexer 7B are each configured as one unit, as represented by the second exemplary structure, the first duplexer 7A and the second duplexer 7B can have the same structure.

In the first passband (transmission band) and the second passband (reception band), a transmission characteristic of the first filter (first transmission filter 5TA) and a transmission characteristic of the third filter (second transmission filter 5TB) may be the same. Also, in the transmission band and the reception band, a transmission characteristic of the second filter (first reception filter 5RA) and a transmission characteristic of the fourth filter (second reception filter 5RB) may be the same. At any frequency included in the transmission band and the reception band, a delay time of the first transmission filter 5TA and a delay time of the second transmission filter 5TB may be the same. At the frequency described above, a delay time of the first reception filter 5RA and a delay time of the second reception filter 5RB may be the same.

In this case, for example, in the transmission band and the reception band, the effect of the cancellation described above is improved, and the isolation characteristics are improved. In simulation calculation performed by the inventor of the present application, an isolation of −60 dB to −70 dB in the reception band and the transmission band with the first duplexer 7A alone was able to be improved to −90 dB to −100 dB by adding the second duplexer 7B (i.e., an improved isolation of 30 dB to 40 dB was able to be achieved).

The phase shifter 9 may be constituted by a transmission line. This transmission line may have a length equivalent to half the wavelength (λ/2) of a signal propagating through the transmission line and having the same frequency as any frequency included in the first passband (transmission band), the second passband (reception band), and a band therebetween (e.g., the center frequency of any of the three bands described above). This λ/2 transmission line may be disposed in any of the following four ranges (positions): between the first transmission filter 5TA and the first branch point 19T at which the path from the first terminal (transmission terminal 3T) branches off toward the first filter (first transmission filter 5TA) and the fourth filter (second transmission filter 5TB); between the first branch point 19T and the second reception filter 5RB; between the first reception filter 5RA and the second branch point 19R at which the path from the second terminal (reception terminal 3R) branches off toward the second filter (first reception filter 5RA) and the third filter (second transmission filter 5TB); and between the second branch point 19R and the second transmission filter 5TB.

In this case, for example, the configuration is simplified because the phase shifter 9 can be provided simply by increasing the length of the wiring line in one of the four ranges described above. Also, the design for impedance matching of the phase shifter 9 is simpler than an embodiment where the phase shifter 9 is constituted by parts distributed at a plurality of positions.

As represented by the first and second exemplary structures, the duplexer 1 may include a multilayer substrate (21A or 21B) and one or more chips (23 or 25) mounted on the multilayer substrate. The multilayer substrate may include the transmission line constituting the phase shifter 9. The one or more chips (23 or 25) may include the first filter (first transmission filter 5TA), the second filter (first reception filter 5RA), the third filter (second transmission filter 5TB), and the fourth filter (second reception filter 5RB).

In this case, for example, the duplexer 1 is made by simply providing a transmission line serving as the phase shifter 9 on the multilayer substrate 21A or 21B while implementing a filter requiring a specific structure and/or material, such as an acoustic wave filter, by using the chip 23 or 25. That is, the configuration is simple.

As represented by the first exemplary structure, the duplexer 1 may include the multilayer substrate 21A and first to fourth chips (23) mounted on the multilayer substrate 21A. The multilayer substrate 21A may include the common terminal (antenna terminal 3A), the first terminal (transmission terminal 3T), the second terminal (reception terminal 3R), and the node 17. The first chip (23) may include the first filter (first transmission filter 5TA). The second chip (23) may include the second filter (first reception filter 5RA). The third chip (23) may include the third filter (second transmission filter 5TB). The fourth chip may include the fourth filter (second reception filter 5RB). The first chip (first transmission filter 5TA) and the third chip (second transmission filter 5TB) may have the same configuration. The second chip (first reception filter 5RA) and the fourth chip (second reception filter 5RB) may have the same configuration.

In this case, for example, the two transmission filters 5T, which have the same configuration, have the same various characteristics over a wide frequency band. The same applies to the two reception filters 5R. Therefore, for example, a leakage signal and a cancellation signal are more likely to have the same strength, and the phase shifter 9 is more likely to make the phases of these signals opposite. This increases the effect of improving isolation characteristics. As well as the leakage signal and the cancellation signal, for example, nonlinear distortions generated in the two transmission filters 5T are expected to have opposite phases and cancel each other out. Also, for example, using the same chips for the two transmission filters 5T (and the two reception filters 5R) improves productivity.

As represented by the second exemplary structure, the duplexer 1 may include the multilayer substrate 21B and fifth and sixth chips (25) mounted on the multilayer substrate 21B. The multilayer substrate 21B may include the common terminal (antenna terminal 3A), the first terminal (transmission terminal 3T), the second terminal (reception terminal 3R), and the node 17. The fifth and sixth chips (25) may have the same configuration. The fifth and sixth chips (25) may each include a third terminal (31A), a fourth terminal (31T), a fifth terminal (31R), a fifth filter (transmission filter 5T), and a sixth filter (reception filter 5R). The transmission filter 5T may be configured to connect the terminal 31A to the terminal 31T. The reception filter 5R may be configured to connect the terminal 31A to the terminal 31R. In the fifth chip (first duplexer 7A), the terminal 31A may be connected to the common terminal (antenna terminal 3A), the terminal 31T may be connected to the first terminal (transmission terminal 3T), and the terminal 31R may be connected to the second terminal (reception terminal 3R). Thus, the fifth filter (transmission filter 5T) may constitute the first filter (first transmission filter 5TA) and the sixth filter (reception filter 5R) may constitute the second filter (first reception filter 5RA). In the sixth chip (second duplexer 7B), the terminal 31A may be connected to the node 17, the terminal 31T may be connected to the reception terminal 3R, and the terminal 31R may be connected to the transmission terminal 3T. Thus, the sixth filter (reception filter 5R) may constitute the third filter (second reception filter 5RB), and the fifth filter (transmission filter 5T) may constitute the fourth filter (second transmission filter 5TB).

In this case, for example, the two duplexers 7, which have the same configuration, have the same various characteristics over a wide frequency band. Therefore, a leakage signal and a cancellation signal are more likely to have the same strength, and the phase shifter 9 is more likely to make the phases of these signals opposite. This increases the effect of improving isolation characteristics. As well as the leakage signal and the cancellation signal, for example, nonlinear distortions generated in the two duplexers 7 are expected to have opposite phases and cancel each other out. Also, for example, using the same chips 25 for the two duplexers 7 improves productivity.

The duplexer 1 may include the resistive element 11 connected to the node 17.

In this case, as described above, the influence of the antenna terminal 3A on a leakage signal can be reproduced in the cancellation signal. This can improve isolation characteristics. Also, for example, since the duplexer 1 includes the resistive element 11, the burden of designing a circuit board (not illustrated) on which the duplexer 1 is mounted is reduced.

The communication apparatus 151 may include the duplexer 1, the antenna 159 connected to the common terminal (antenna terminal 3A), the resistive element 11 (which may either be included or not included in the duplexer 1) connected to the node 17, and an integrated circuit element (RF-IC 153) connected to the first terminal (transmission terminal 3T) and the second terminal (reception terminal 3R).

The communication apparatus 151 has isolation characteristics improved by the effect of the duplexer 1 described above.

In the embodiments described above, the duplexer 1 is an example of the branching filter. The first transmission filter 5TA is an example of the first filter. The first reception filter 5RA is an example of the second filter. The second transmission filter 5TB is an example of the third filter. The second reception filter 5RB is an example of the fourth filter. The antenna terminal 3A is an example of the common terminal. The transmission terminal 3T is an example of the first terminal. The reception terminal 3R is an example of the second terminal. The transmission band is an example of the first passband. The reception band is an example of the second passband. The four chips 23 are examples of the first to fourth chips. The two chips 25 are examples of the fifth and sixth chips. The terminal 31A is an example of the third terminal. The terminal 31T is an example of the fourth terminal. The terminal 31R is an example of the fifth terminal. The transmission filter 5T of the chip 25 is an example of the fifth filter. The reception filter 5R of the chip 25 is an example of the sixth filter. The RF-IC 153 is an example of the integrated circuit element.

The techniques according to the present disclosure are not limited to those in the embodiments described above, and may be implemented in various embodiments.

For example, the duplexer described in an embodiment may be part of a quadplexer. In another perspective, three or more filters may be connected to the common terminal (or antenna terminal in an embodiment). The branching filter may be a diplexer (or may be configured to be considered as a diplexer) configured to combine two signals from the first terminal and the second terminal and output the resulting signal to the common terminal, or separate signals from the common terminal and output the resulting signals to the first terminal and the second terminal. In another perspective, the duplexer does not need to be one that is configured to be considered only as a duplexer before being incorporated into a communication device or the like.

### REFERENCE SIGNS

1: duplexer (branching filter), 3A: antenna terminal (common terminal), 3T: transmission terminal (first terminal), 3R: reception terminal (second terminal), 5TA: first transmission filter (first filter), 5RA: first reception filter (second filter), 5TB: second transmission filter (third filter), 5RB: second reception filter (fourth filter), 9: phase shifter (180° phase shifter), 17: node

1. A branching filter comprising:
a first filter configured to connect a common terminal to a first terminal and corresponding to a first passband;
a second filter configured to connect the common terminal to a second terminal and corresponding to a second passband not overlapping the first passband;
a third filter configured to connect a node disposed at a branch point to the second terminal and corresponding to the first passband;
a fourth filter configured to connect the node to the first terminal and corresponding to the second passband; and
a 180° phase shifter disposed closer to the first terminal than the first filter and the fourth filter are, or disposed closer to the second terminal than the second filter and the third filter are, the 180° phase shifter being configured to make phases of output signals from a path extending from the first terminal through the first filter and the second filter to the second terminal and a path extending from the first terminal through the fourth filter and the third filter to the second terminal opposite each other, the output signals being based on the same input signal to the paths.

2. The branching filter according to claim 1, wherein
in the first passband and the second passband,
a transmission characteristic of the first filter and a transmission characteristic of the third filter are the same, and
a transmission characteristic of the second filter and a transmission characteristic of the fourth filter are the same; and
at any frequency comprised in the first passband and the second passband,
a delay time of the first filter and a delay time of the third filter are the same, and
a delay time of the second filter and a delay time of the fourth filter are the same.

3. The branching filter according to claim 1, wherein
the 180° phase shifter is constituted by a transmission line;
the transmission line has a length equivalent to half a wavelength of a signal propagating through the transmission line, the signal having the same frequency as any frequency comprised in the first passband, the second passband, and a band therebetween; and
the transmission line is disposed
between the first filter and a first branch point at which a path from the first terminal branches off toward the first filter and the fourth filter,
between the first branch point and the fourth filter,
between the second filter and a second branch point at which a path from the second terminal branches off toward the second filter and the third filter, or
between the second branch point and the third filter.

4. The branching filter according to claim 1, comprising
a multilayer substrate comprising a transmission line constituting the 180° phase shifter; and
one or more chips mounted on the multilayer substrate and comprising the first filter, the second filter, the third filter, and the fourth filter.

5. The branching filter according to claim 1, comprising:
a multilayer substrate comprising the common terminal, the first terminal, the second terminal, and the node;
a first chip mounted on the multilayer substrate and comprising the first filter;
a second chip mounted on the multilayer substrate and comprising the second filter;
a third chip mounted on the multilayer substrate and comprising the third filter; and
a fourth chip mounted on the multilayer substrate and comprising the fourth filter,
wherein the first chip and the third chip have the same configuration; and
the second chip and the fourth chip have the same configuration.

6. The branching filter according to claim 1, comprising:
a multilayer substrate comprising the common terminal, the first terminal, the second terminal, and the node; and
a fifth chip and a sixth chip mounted on the multilayer substrate and having the same configuration,
wherein the fifth chip and the sixth chip each comprises
a third terminal, a fourth terminal, and a fifth terminal,
a fifth filter configured to connect the third terminal to the fourth terminal, and
a sixth filter configured to connect the third terminal to the fifth terminal;
in the fifth chip, the third terminal is connected to the common terminal, the fourth terminal is connected to the first terminal, and the fifth terminal is connected to the second terminal to allow the fifth filter to constitute the first filter and allow the sixth filter to constitute the second filter; and
in the sixth chip, the third terminal is connected to the node, the fourth terminal is connected to the second terminal, and the fifth terminal is connected to the first terminal to allow the sixth filter to constitute the third filter and allow the fifth filter to constitute the fourth filter.

7. The branching filter according to claim 1, comprising a resistive element connected to the node.

8. A communication apparatus comprising:
the branching filter according to claim 1;
an antenna connected to the common terminal;
a resistive element connected to the node; and
an integrated circuit element connected to the first terminal and the second terminal.
